(19) United States
(12) Patent Application Publication
(10) Pub. No.: US 2007/0295960 A1
(43) Pub. Date: Dec. 27, 2007

(54) SEMICONDUCTOR DEVICE, ELECTRO-OPTICAL DEVICE, ELECTRONIC APPARATUS, AND METHOD OF PRODUCING SEMICONDUCTOR DEVICE

(75) Inventors: Soichi MORIYA, Chino (JP); Takeo KAWASE, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/758,728

(22) Filed: Jun. 6, 2007

(30) Foreign Application Priority Data
Jun. 9, 2006 (JP) 2006-161500

(51) Int. Cl. H01L 29/08

(52) U.S. Cl. 257/40

(57) ABSTRACT

A semiconductor device includes an organic semiconductor transistor provided on a substrate; a data line connected to a source electrode or a drain electrode of the organic semiconductor transistor; and a gate line that is disposed so as to intersect the data line and that is connected to a gate electrode of the organic semiconductor transistor. In the semiconductor device, the gate line includes the gate electrode, a first gate line that transmits signals to the gate electrode, and a second gate line intersecting the data line, with an interlayer insulation layer therebetween; the gate electrode, the first gate line, and the second gate line are connected in series; and the electric conductivity of the first gate line is higher than the electric conductivity of the gate electrode and the electric conductivity of the second gate line.

### BACKGROUND

1. Technical Field

The present invention relates to a semiconductor device, an improvement in a method of producing a semiconductor device, and an electro-optical device and an electronic apparatus including the semiconductor device.

2. Related Art

A process for producing semiconductor devices, such as an organic semiconductor transistor, using an organic semiconductor material has been proposed. For example, JP-A-2005-215616 discloses an example of a process for producing an active matrix substrate in which pixels, data wiring, and peripheral wiring are formed by a single photolithography process, and various functional films are then formed by a liquid phase process using liquid materials. For example, a printing method such as an ink jet method is used for forming the films using the liquid materials. More specifically, a conductive organic substance such as polyethylenedioxythiophene (PEDOT) is applied on a substrate and then dried, thus forming circuit wiring.

However, a conductive organic substance, such as PEDOT, used for a printing method has a high resistivity. In addition, when wiring is formed by printing a dispersion liquid containing a metal and then drying the dispersion liquid, the wiring cannot have a high electric conductivity. The reason for this is as follows. The electric conductivity of the dispersion liquid itself is not high, and the annealing temperature of the applied and dried metal layer cannot be increased because characteristics of the organic semiconductor are degraded by the annealing and the glass transition temperature of a plastic substrate has an upper limit. Accordingly, for example, when a gate wiring group of a large-screen active matrix display panel with a high definition is formed by a printing method, delay time of driving signals for driving a pixel-driving transistor is increased because of a high gate-wiring resistance.

Furthermore, in a process of producing a gate insulating layer of an organic semiconductor transistor, when the gate insulating layer is formed by, for example, spin coating on the entire surface of a substrate and gate electrodes, gate wiring, and the like are then formed by a printing method, it is necessary to form contact holes on the gate insulating layer in order to establish electrical connection between the gate wiring and peripheral wiring. When an organic semiconductor layer is formed on a substrate and the contact holes are then formed, the use of a photolithography process using a resist made of an organic substance, which is similar to the material of the organic semiconductor layer, easily damages the organic semiconductor layer. In order to prevent this problem, the contact holes may be formed on the gate insulating layer by a physical method with a stylus or the like. However, such a method is time-consuming and is not suitable for mass production.

### SUMMARY

An advantage of an aspect of the invention is that it provides a semiconductor device, an electro-optical device, and an electronic apparatus in which the resistance of a gate line (gate wiring) which transmits gate-driving signals can be reduced in an organic semiconductor device used in an active matrix display.

An advantage of another aspect of the invention is that it provides a semiconductor device, an electro-optical device, and an electronic apparatus in which response characteristics are improved by reducing the resistance of a gate line without forming contact holes.

An advantage of another aspect of the invention is that it provides a method of producing a semiconductor device in which the resistance of a gate line (gate wiring) of an organic semiconductor device used in an active matrix display can be reduced.

A semiconductor device according to an aspect of the invention includes an organic semiconductor transistor provided on a substrate; a data line connected to a source electrode or a drain electrode of the organic semiconductor transistor; and a gate line that is disposed so as to intersect the data line and that is connected to a gate electrode of the organic semiconductor transistor. In the semiconductor device, the gate line includes the gate electrode, a first gate line that transmits signals to the gate electrode, and a second gate line intersecting the data line, with an interlayer insulation layer therebetween; the gate electrode, the first gate line, and the second gate line are connected in series; and the electric conductivity of the first gate line is higher than the electric conductivity of the gate electrode and the electric conductivity of the second gate line.

According to this structure, signal delay in the gate line (gate signal line) can be reduced.

The second gate line and the gate electrode are preferably composed of the same film disposed above an organic semiconductor layer of the organic semiconductor transistor. The second gate line and the gate electrode are preferably provided in an integrated manner. A gate insulating layer of the organic semiconductor transistor and the interlayer insulation layer are preferably composed of the same film disposed above an organic semiconductor layer of the organic semiconductor transistor.

Accordingly, the film formation and the patterning can be performed by a printing method such as an ink jet method. Consequently, damage on the organic semiconductor layer due to etching or a thermal process can be prevented.

The gate insulating layer of the organic semiconductor transistor and the interlayer insulation layer provided between the data line and the second gate line are preferably provided in an integrated manner. In this case, the number of times of application (discharge) in the printing method can be reduced.

The line width of the first gate line is preferably smaller than the line width of the gate electrode and the line width of the second gate line. Accordingly, the aperture efficiency of pixels in an active matrix display can be increased.

The second gate line and the gate electrode are preferably formed by a printing method. The gate insulating layer of the organic semiconductor transistor and the interlayer insulation layer are preferably formed by a printing method. Accordingly, damage on the organic semiconductor layer due to etching or a thermal process can be prevented. Furthermore, since patterning can be directly performed by the printing method, the number of steps in the production can be decreased.

When any of the above-described semiconductor devices is used in an electro-optical device such as an organic electroluminescent (EL) device, a liquid crystal display device, or an electrophoresis display device, or an electronic apparatus, the performance of the device or the apparatus can be improved.

An electro-optical device according to an aspect of the invention includes a pixel electrode substrate having a plurality of data lines extending in one direction, a plurality of gate lines that are disposed so as to intersect the plurality of data lines, a plurality of pixel electrodes disposed in areas defined by the plurality of data lines and the plurality of gate lines, and a plurality of organic semiconductor transistors disposed near the intersections of the data lines and the gate lines. In the electro-optical device, the gate lines each include a gate electrode of the organic semiconductor transistor, a first gate line that transmits signals to the gate electrode, and a second gate line intersecting the data line, with an interlayer insulation layer therebetween; the gate electrode, the first gate line, and the second gate line are connected in series; and the electric conductivity of the first gate line is higher than the electric conductivity of the gate electrode and the electric conductivity of the second gate line.

According to this structure, the resistance can be reduced compared with the case where the entire gate line is formed by a printing method, and signal delay in the gate line can be reduced.

A method of producing a semiconductor device according to an aspect of the invention includes forming a first gate line, at least two source/drain electrodes, and a data line on an insulating substrate; forming an organic semiconductor layer between the source/drain electrodes; forming a gate insulating layer and an interlayer insulation layer on the organic semiconductor layer and the data line, respectively, by a printing method; and forming a gate electrode connected to the first gate line and a second gate line on the gate insulating layer and the interlayer insulation layer, respectively, by a printing method.

According to this method, signal delay in the gate line (gate signal line) can be reduced. Furthermore, damage on the organic semiconductor layer due to etching or a thermal process can be prevented.

In the method, preferably, the resistance of the first gate line is reduced by forming the first gate line, the source/drain electrodes, and the data line by a non-printing method, or by a printing method followed by a heat treatment of a conductive material at a temperature higher than the temperature at which the organic semiconductor layer is degraded. Accordingly, the resistance of the first gate line can be reduced. As regards a preferred example of the non-printing method, a metal material is deposited by vapor deposition or sputtering to form the gate line. Accordingly, a gate line (gate electrode) having a low resistance can be produced.

In the method, the gate insulating layer and the interlayer insulation layer are preferably formed in an integrated manner. The gate electrode and the second gate line are preferably formed in an integrated manner. In this case, the production process can be simplified.

In the method, the first gate line is preferably formed so that the line width of the first gate line is smaller than the line width of the gate electrode and the line width of the second gate line. Accordingly, the area of the gate line is decreased, and the area of the pixel electrode can be relatively increased. Consequently, the aperture efficiency of pixels in an active matrix-type pixel substrate can be increased.

### BRIEF DESCRIPTION OF THE DRAWINGS

The invention will be described with reference to the accompanying drawings, wherein like numbers reference like elements.

FIGS. 1A to 1E are process drawings illustrating the steps of producing an organic semiconductor transistor (semiconductor device) of a first embodiment.

FIG. 2 is a plan view illustrating the structure of the organic semiconductor transistor of the first embodiment.

FIGS. 3A to 3D are process drawings illustrating the steps of producing an organic semiconductor transistor of a second embodiment.

FIG. 4 is a plan view illustrating the structure of the organic semiconductor transistor of the second embodiment.

FIGS. 5A to 5E are process drawings illustrating the steps of producing an organic semiconductor transistor of a third embodiment.

FIG. 6 is a plan view illustrating the structure of the organic semiconductor transistor of the third embodiment.

FIGS. 7A to 7D are process drawings illustrating the steps of producing an organic semiconductor transistor of a fourth embodiment.

FIG. 8 is a plan view illustrating the structure of the organic semiconductor transistor of the fourth embodiment.

FIG. 9 is a plan view illustrating an example of an active matrix substrate including an organic semiconductor transistor of the invention.

FIG. 10 is a plan view illustrating an organic semiconductor transistor of a fifth embodiment.

FIGS. 11A to 11D are views illustrating examples of electronic apparatuses including an organic semiconductor transistor of the invention.

### DESCRIPTION OF EXEMPLARY EMBODIMENTS

Preferred embodiments of the invention will now be described with reference to the drawings. In the figures, common components are assigned the same reference numerals.

### First Embodiment

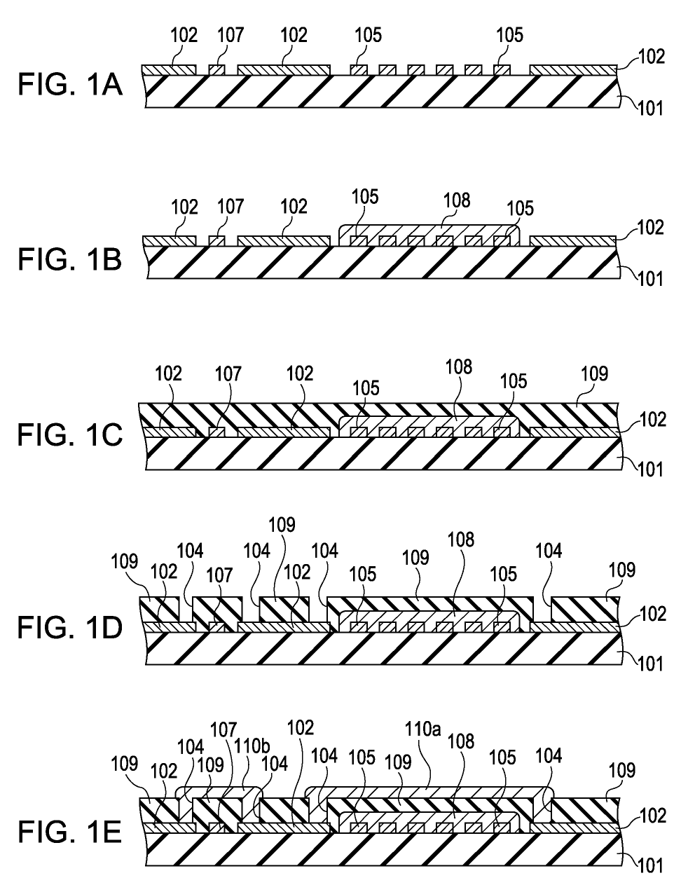

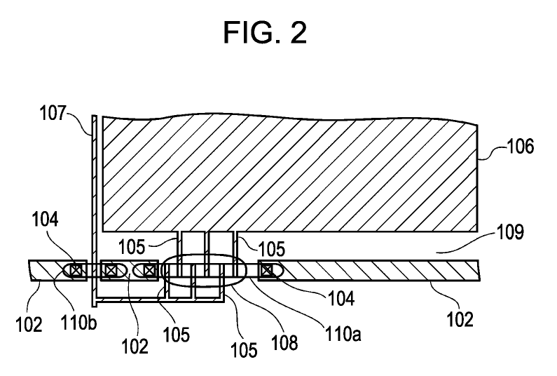

FIGS. 1A to 1E and FIG. 2 show an example in which an organic semiconductor transistor of the invention is used in a drive circuit of pixels of a display. FIGS. 1A to 1E are process drawings illustrating the steps of producing the organic semiconductor transistor, which is a semiconductor device. FIG. 2 is a plan view of the pixel-driving circuit.

In this embodiment, gate lines (wiring) having a low resistance are formed on a substrate, and connection of the gate lines and formation of gate electrodes are performed by a single printing method.

First, as shown in FIG. 1A, a first gate line 102, a data line 107, source/drain electrodes 105, a pixel electrode 106 (see FIG. 2), terminals for connecting to an external driving unit, external wiring (not shown), and the like are formed on an insulating substrate 101 at the same time.

For example, a plastic substrate, such as a polyethylene terephthalate (PET) substrate, or a glass substrate can be used as the insulating substrate 101. Other examples of the substrate material include plastic substrates (resin substrates) made of polyethylene naphthalate (PEN), polyethersulfone (PES), polycarbonate (PC), an aromatic polyester (liquid crystal polymer), or a polyimide (PI). In addition, a glass substrate, a silicon substrate, a metal substrate, a gallium arsenide substrate, or the like can also be used as long as the substrate is flexible.

The first gate line 102, the data line 107, the source/drain electrodes 105, the pixel electrode 106, and the like can be formed by depositing a metal, such as aluminum, nickel, copper, titanium, silver, gold, or platinum, by vapor deposition or sputtering, and then patterning the deposited metal film by a photolithography process.

Alternatively, these components may be formed by discharging (or applying) a solution containing metal fine particles using a printing method, such as an ink jet (droplet discharge) method, and then drying the solution by heating. When such a solution is applied and a solvent is then removed to use the metal fine particles, a heat treatment may be performed in order to improve electrical contact between the metal fine particles. The heat treatment is usually performed in air but may be performed in an inert gas atmosphere, such as nitrogen, argon, or helium, as required. Examples of the metal fine particles include silver, aluminum, and gold particles.

In this embodiment, the ink jet (droplet discharging) method, which is advantageous in terms of noncontacting, is employed. Alternatively, other printing methods, such as screen printing, flexographic printing, offset printing, and microcontact printing may also be employed.

The heat treatment at this stage can be performed at a relatively high temperature in consideration of only heat resistance of the substrate because the heat resistance temperature of an organic semiconductor material described below need not be considered. Consequently, a first gate line 102 and the like having a low resistance (high electric conductivity) can be produced.

Subsequently, a cleaning treatment is performed by conducting an oxygen plasma treatment on the substrate. As shown in FIG. 1B, a fluorene-thiophene copolymer (F8T2), which is an organic semiconductor, is then dropped by an ink jet method and annealed. Accordingly, an organic semiconductor layer 108 having a thickness of about 50 nm is formed so as to cover a channel portion of a transistor disposed between the plurality of source/drain electrodes 105.

Either a low-molecular-weight organic semiconductor material or a polymer organic semiconductor material can be used as the organic semiconductor material.

Examples of the polymer organic semiconductor material include poly(3-alkylthiophene) such as poly(3-hexylthiophene) (P3HT) and poly(3-octylthiophene), poly(2,5-thienylene vinylene) (PTV), poly(para-phenylene vinylene) (PPV), poly(9,9-dioctylfluorene-co-bis-N,N′-(4-methoxyphenyl)-bis-N,N′-phenyl-1,4-phenylenediamine) (PFMO), poly(9,9-dioctylfluorene-co-benzothiadiazole) (BT), fluorene-triallylamine copolymers, triallylamine polymers, and fluorene-bithiophene copolymers.

Examples of the low-molecular-weight organic semiconductor material include C60; metal phthalocyanines and substituted derivatives thereof; acene molecule materials such as anthracene, tetracene, pentacene, and hexacene; α-oligothiophenes such as quarterthiophene (4T), sexithiophene (6T), octithiophene (8T), dihexylquarterthiophene (DH4T), and dihexylsexithiophene (DH6T).

As shown in FIG. 1C, a gate insulating layer 109 is formed so as to cover the organic semiconductor layer 108. The gate insulating layer 109 can be formed by spin coating, dipping, or printing such as an ink jet method, using an acrylic resin, an epoxy resin, or an ester resin. In this embodiment, the gate insulating layer 109 is formed on the entire surface of the substrate by spin coating. The gate insulating layer 109 disposed on areas other than the transistor area functions as an interlayer insulation layer.

Alternatively, the gate insulating layer 109 may be formed only on required areas by a printing method, as in a second embodiment described below.

As shown in FIG. 1D, contact holes 104 are formed by removing a part of the gate insulating layer 109 at each side of the transistor area on the gate line 102 and each side of the data line 107 on the gate line 102.

The contact holes 104 can be formed by, for example, photolithography. More specifically, a photoresist is applied on the gate insulating layer 109. The photoresist layer is then exposed using a mask having the pattern of the contact holes 104 and developed, thus forming a resist mask. The gate insulating layer 109 is then etched using this resist mask to form the contact holes 104.

Alternatively, a photosensitive polymer (photoresist) may be used as the gate insulating layer 109. More specifically, a photosensitive polymer is applied on the substrate. The photosensitive polymer is then exposed using a mask having the pattern of the contact holes and developed. Thus, the contact holes may be directly formed on the gate insulating layer 109. That is, the contact holes may be formed by directly exposing the gate insulating layer 109 made of the photosensitive polymer.

When the gate insulating layer 109 is formed of a resin, a part of the gate insulating layer 109 may be removed by discharging (or applying) a solvent that can dissolve the resin at desired positions by an ink jet method or the like, thereby forming a gate insulating layer 109 having the contact holes 104.

As shown in FIG. 1E, a gate electrode 110a is formed between the contact holes 104 disposed at both sides of the transistor area on the gate insulating layer 109 so as to cover or cross over the channel portion of the transistor. Furthermore, a second gate line 110b is formed between the contact holes 104 disposed at both sides of the data line 107.

The gate electrode 110a and the second gate line 110b are formed by, for example, discharging or applying a dispersion liquid of metal particles or a conductive polymer, such as polyethylenedioxythiophene (PEDOT), by an ink jet method or other printing method, and annealing or drying it at an appropriate temperature at which the organic semiconductor layer 108 is not adversely affected.

As a result, as shown in FIG. 1E, a part of the first gate line 102, the second gate line 110b, another part of the first gate line 102, the gate electrode 110a, and another part of the first gate line 102 are connected in series, thus forming a signal line (gate line) for transmitting gate-driving signals to the next stage transistor.

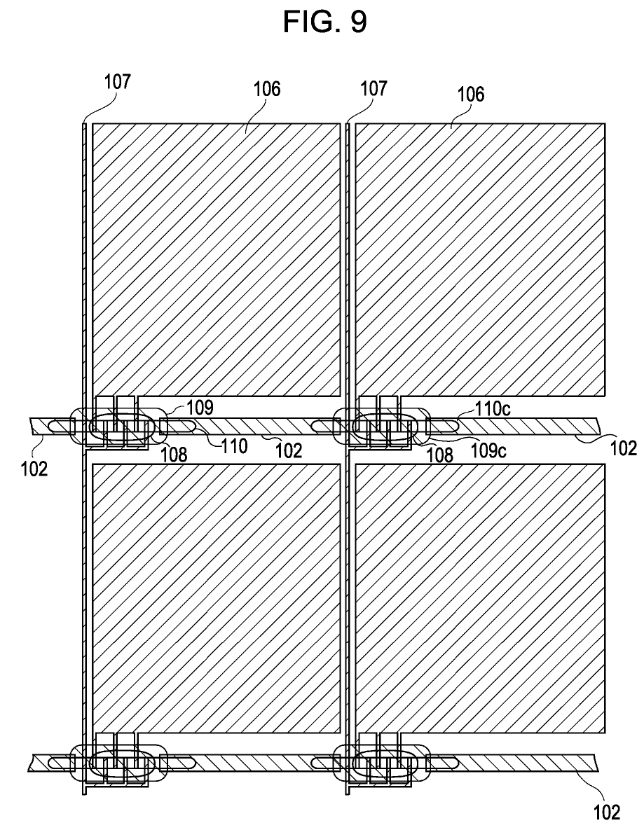

Furthermore, according to need, a protective layer and the like (not shown) are formed on the substrate including pixel electrodes. As shown in FIG. 2 and FIG. 9 described below, the substrate is used as a pixel electrode substrate (active matrix substrate) of a liquid crystal display device, an electrophoresis display device, or the like.

### Second Embodiment

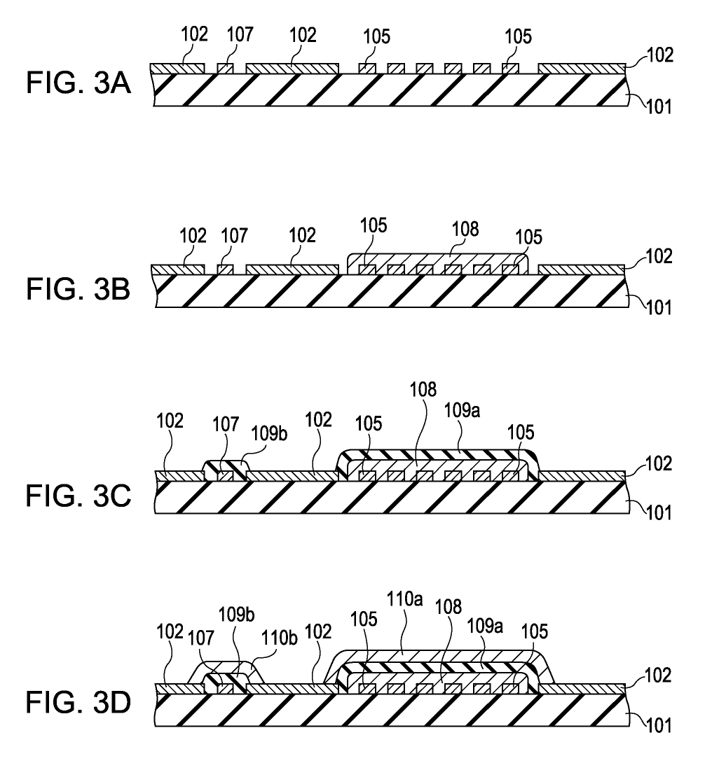

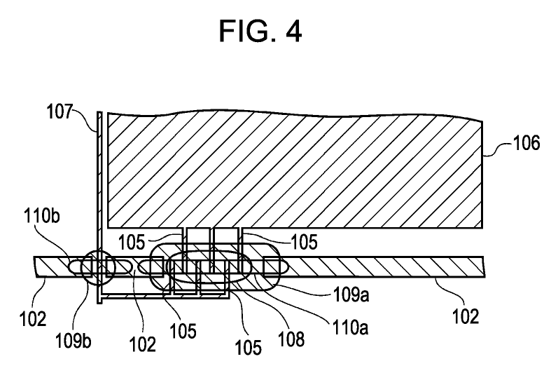

FIGS. 3A to 3D and FIG. 4 show a second embodiment.

FIGS. 3A to 3D are process drawings illustrating the steps of producing an organic semiconductor transistor, which is a semiconductor device. FIG. 4 is a plan view of a pixel-driving circuit. In FIGS. 3A to 3D and FIG. 4, components corresponding to those in FIGS. 1A to 1E and FIG. 2 are assigned the same reference numerals, and a description of the common structure is omitted.

First, as shown in FIG. 3A, a first gate line 102, a data line 107, source/drain electrodes 105, a pixel electrode 106 (see FIG. 4), terminals for connecting to an external driving unit, and external wiring (not shown) are formed on an insulating substrate 101 at the same time.

Subsequently, a cleaning treatment is performed by conducting an oxygen plasma treatment on the substrate. As shown in FIG. 3B, a fluorene-thiophene copolymer (F8T2), which is an organic semiconductor, is then dropped by an ink jet method and annealed. Accordingly, an organic semiconductor layer 108 having a thickness of about 50 nm is formed so as to cover a channel portion of a transistor disposed between the plurality of source/drain electrodes 105.

As shown in FIG. 3C, a gate insulating layer 109a and an interlayer insulation layer 109b are formed so as to cover the organic semiconductor layer 108 and the data line 107, respectively. The gate insulating layer 109a and the interlayer insulation layer 109b can be formed by a printing method, such as an ink jet method, using an acrylic resin, an epoxy resin, or an ester resin. In this embodiment, the gate insulating layer 109a and the interlayer insulation layer 109b are formed on each area of the substrate by the ink jet method.

As shown in FIG. 3D, a gate electrode 110a is formed on the gate insulating layer 109a so as to cover or cross over the channel portion of the transistor. Furthermore, a second gate line 110b is formed on the data line 107, with the interlayer insulation layer 109b therebetween. The gate electrode 110a and the interlayer insulation layer 109b are formed by a printing method, such as an ink jet method. Parameters such as materials used in the above process are the same as those of corresponding components in the first embodiment.

In this second embodiment, contact holes 104, which are formed in the first embodiment, are not used. Therefore, in the second embodiment, as shown in FIG. 3C, the gate insulating layer 109a is not formed on the entire surface of the substrate, but the gate insulating layer 109a and the interlayer insulation layer 109b are partly formed (patterned) by a printing method, such as an ink jet method, so as to expose the gate line 102 on the surface. In this embodiment, the gate insulating layer 109a and the interlayer insulation layer 109b are formed by a single step using a printing method. As described above, an acrylic resin, an epoxy resin, or an ester resin can be used for the gate insulating layer 109a and the like.

Alternatively, the gate insulating layer 109a and the interlayer insulation layer 109b may be formed by separate steps. However, in view of throughput, these layers are preferably formed at the same time by a single step. The gate insulating layer 109a and the interlayer insulation layer 109b can be formed by a known photolithography process. However, since the organic semiconductor layer 108 has been already formed, the above-described printing method is preferably employed.

In addition, as shown in FIG. 4, from the standpoint that insulation from the peripheral area is ensured, the width of the gate insulating layer 109a is preferably larger than the widths of the first gate line 102, the second gate line 110b, and the gate electrode 110a.

### Third Embodiment

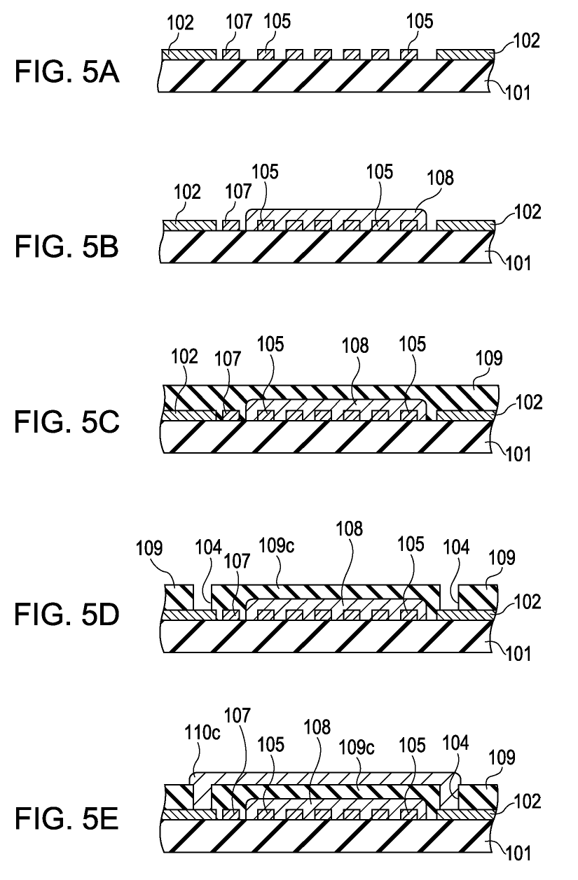

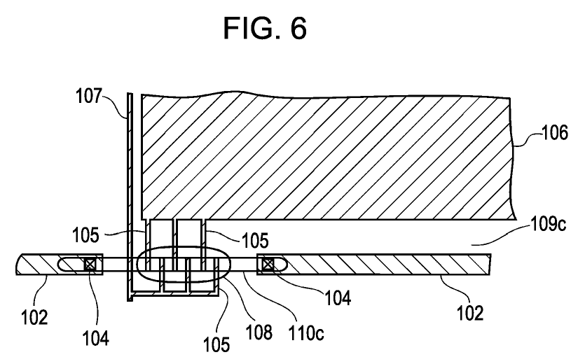

FIGS. 5A to 5E and FIG. 6 show a third embodiment. FIGS. 5A to 5E are process drawings illustrating the steps of producing an organic semiconductor transistor, which is a semiconductor device. FIG. 6 is a plan view of a pixel-driving circuit. In FIGS. 5A to 5E and FIG. 6, components corresponding to those in FIGS. 1A to 1E and FIG. 2 are assigned the same reference numerals, and a description of the common structure is omitted.

In the third embodiment, the second gate line 110b, the first gate line 102, and the gate electrode 110a which are described in the first embodiment (FIG. 1E) are constituted by a single gate electrode wiring 110c, as shown in FIG. 5E. This structure is advantageous in that the number of patterns can be reduced, thereby reducing the number of times of applying a liquid by the ink jet method.

### Fourth Embodiment

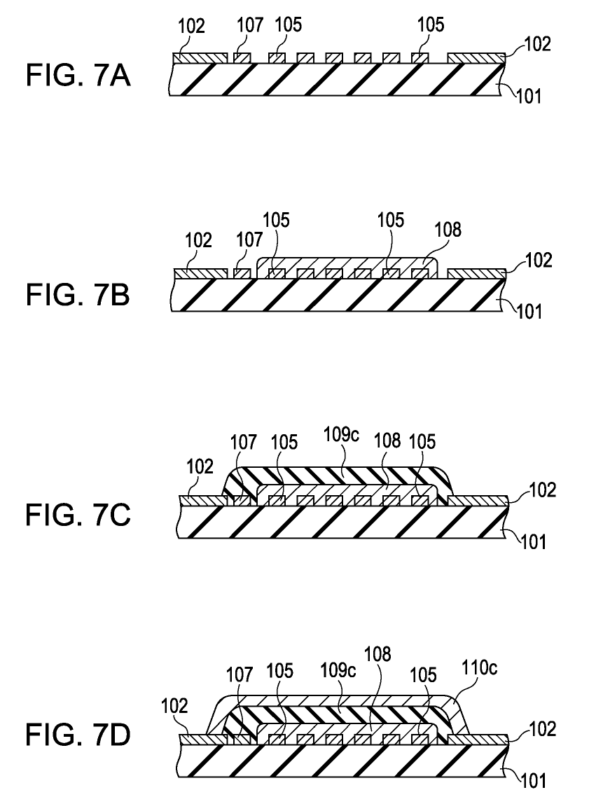

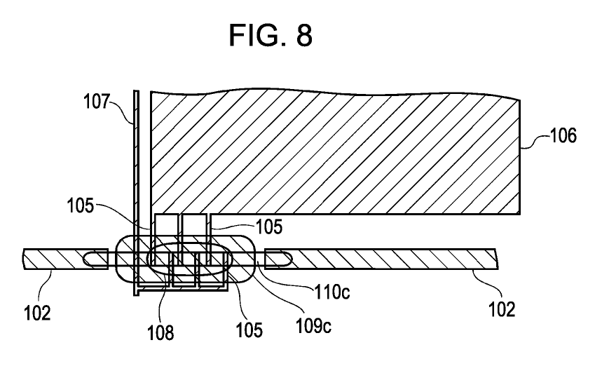

FIGS. 7A to 7D, FIG. 8, and FIG. 9 show a fourth embodiment. FIGS. 7A to 7D are process drawings illustrating the steps of producing an organic semiconductor transistor, which is a semiconductor device. FIG. 8 is a plan view of a pixel-driving circuit. FIG. 9 is a plan view illustrating an example of an active matrix substrate on which a plurality of (four) pixel-driving circuits are arranged. In FIGS. 7A to 7D, FIG. 8, and FIG. 9, components corresponding to those in FIG. 2 and FIGS. 3A to 3D are assigned the same reference numerals, and a description of the common structure is omitted.

In this fourth embodiment, the second embodiment, in which the contact holes need not be formed, and the third embodiment, in which the first gate line 102 and the second gate line 110b intersecting the data line 107 need not be formed because the gate electrode wiring 110c is provided by extending the gate electrode 110a, are combined.

According to this structure, in addition to the above-described advantages, the gate insulating layer 109a and the interlayer insulation layer 109b disposed on the data line 107 are continuously formed as a single gate insulating layer 109c. This structure is suitably formed by a printing method.

### Fifth Embodiment

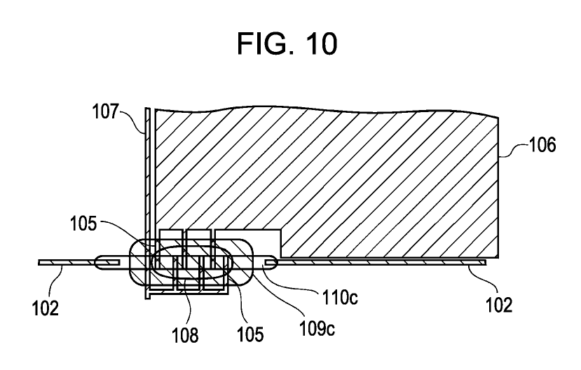

FIG. 10 is a plan view of a pixel-driving circuit according to a fifth embodiment. In FIG. 10, components corresponding to those in FIG. 8 are assigned the same reference numerals, and a description of the common structure is omitted.

In this fifth embodiment, the line width of the first gate line 102 having a low resistance is smaller than the line width of the gate electrode wiring 110c. Accordingly, the wiring area of the gate line is decreased, and the area of the pixel electrode 106 can be increased. Consequently, the aperture efficiency of the display panel can be increased.

In addition, in order to cope with the gate electrode wiring 110c (the gate electrode 110a or the second gate line 110b) having a line width larger than that of the first gate line 102, the pattern of the pixel electrode 106 is designed so as to have a large distance between the gate line 102 and the pixel electrode 106. This structure prevents the generation of a parasitic capacitance caused by overlapping the gate electrode wiring 110c (the gate electrode 110a or the second gate line 110b) with the pixel electrode 106.

As described above, according to the embodiments of the invention, a material having a low resistivity is used for the first gate line 102. Accordingly, the resistance of entire gate line can be reduced, and delay time due to the gate wiring resistance can be decreased. Furthermore, the first gate line 102 can be formed with a high definition. Since the gate electrode 110a, the second gate line 110b, and the gate electrode wiring 110c are formed by a printing method, a substrate with a high definition can be produced at low cost.

The gate electrode 110a, the gate electrode wiring 110c connected to the channel portion of the transistor, and the second gate line 110b for connecting the first gate line 102 disposed at both sides of the data line 107 are formed as a single continuous wiring. Accordingly, the production process can be simplified.

The gate insulating layer 109a and the interlayer insulation layer 109b are patterned by a single process using the same material. Accordingly, the production process can be simplified.

The line width of the first gate line 102 is smaller than the line width of the gate electrode 110a, the line width of the second gate line 110b, or the line width of the gate electrode wiring 110c. Accordingly, a panel with a higher definition can be produced.

### Electronic Apparatus

A description will be made of examples of electronic apparatuses including an organic semiconductor thin-film transistor (TFT) produced by any of the methods described above. In various types of electronic apparatuses, the organic semiconductor TFT according to any of the embodiments can be applied to the production of a liquid crystal display panel, an electroluminescent display panel, or an electrophoresis display panel constituting a display unit; the production of a circuit unit; or the like.

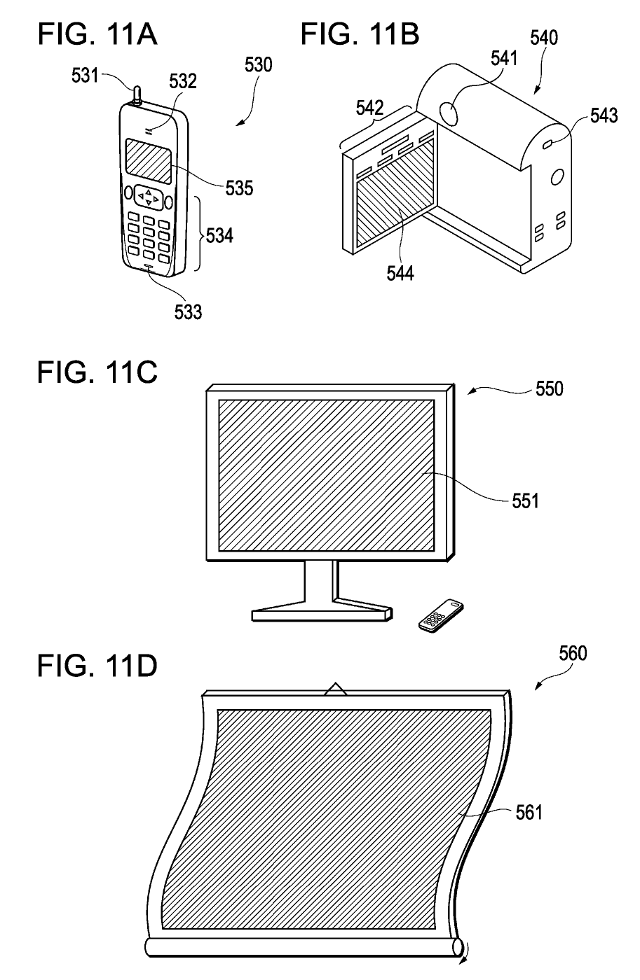

FIGS. 11A to 11D are schematic perspective views illustrating examples of the electronic apparatuses. FIG. 11A shows an application to a cell phone. The cell phone 530 includes an antenna unit 531, a voice output unit 532, a voice input unit 533, an operation unit 534, and a display unit 535.

FIG. 11B shows an application to a video camera. The video camera 540 includes an image-receiving unit 541, an operation unit 542, a voice input unit 543, and a display unit 544.

FIG. 11C shows an application to a television. The television 550 includes a display unit 551.

FIG. 11D shows an application to a roll-up television. The roll-up television 560 includes a display unit 561. The application of the organic semiconductor TFT according to the invention is not limited to the above-described examples. The organic semiconductor TFT of the invention can be applied to various electronic apparatuses. For example, in addition to the above examples, the organic semiconductor TFT of the invention can be applied to a fax machine having a display function, a finder of a digital camera, a portable TV, an electronic notebook, an electric bulletin board, a display for advertisements and public announcements, and the like.

The invention is not limited to the above-described embodiments, and various changes and modifications may be made without departing from the spirit and scope of the invention.

What is claimed is:

1. A semiconductor device comprising:
an organic semiconductor transistor provided on a substrate;
a data line connected to a source electrode or a drain electrode of the organic semiconductor transistor; and
a gate line that is disposed so as to intersect the data line and that is connected to a gate electrode of the organic semiconductor transistor;
wherein the gate line includes the gate electrode, a first gate line that transmits signals to the gate electrode, and a second gate line intersecting the data line, with an interlayer insulation layer therebetween; the gate electrode, the first gate line, and the second gate line are connected in series; and the electric conductivity of the first gate line is higher than the electric conductivity of the gate electrode and the electric conductivity of the second gate line.

2. The semiconductor device according to claim 1, wherein the second gate line and the gate electrode are composed of the same film disposed above an organic semiconductor layer of the organic semiconductor transistor.

3. The semiconductor device according to claim 1, wherein the second gate line and the gate electrode are provided in an integrated manner.

4. The semiconductor device according to claim 1, wherein a gate insulating layer of the organic semiconductor transistor and the interlayer insulation layer are composed of the same film disposed above an organic semiconductor layer of the organic semiconductor transistor.

5. The semiconductor device according to claim 1, wherein a gate insulating layer of the organic semiconductor transistor and the interlayer insulation layer provided between the data line and the second gate line are provided in an integrated manner.

6. The semiconductor device according to claim 1, wherein the line width of the first gate line is smaller than the line width of the gate electrode and the line width of the second gate line.

7. The semiconductor device according to claim 1, wherein the second gate line and the gate electrode are formed by a printing method.

8. The semiconductor device according to claim 1, wherein a gate insulating layer of the organic semiconductor transistor and the interlayer insulation layer are formed by a printing method.

9. An electro-optical device comprising the semiconductor device according to claim 1.

10. An electronic apparatus comprising the semiconductor device according to claim 1.

11. A method of producing a semiconductor device comprising:
forming a first gate line having a low resistance, at least two source/drain electrodes, and a data line on an insulating substrate;
forming an organic semiconductor layer between the source/drain electrodes;
forming a gate insulating layer and an interlayer insulation layer on the organic semiconductor layer and the data line, respectively, by a printing method; and
forming a gate electrode connected to the first gate line and a second gate line on the gate insulating layer and the interlayer insulation layer, respectively, by a printing method.

12. The method of producing a semiconductor device according to claim 11, wherein the resistance of the first gate line is reduced by forming the first gate line, the source/drain electrodes, and the data line by a non-printing method, or by a printing method followed by a heat treatment of a conductive material at a temperature higher than the temperature at which the organic semiconductor layer is degraded.

13. The method of producing a semiconductor device according to claim 11, wherein the gate insulating layer and the interlayer insulation layer are formed in an integrated manner.

14. The method of producing a semiconductor device according to claim 11, wherein the gate electrode and the second gate line are formed in an integrated manner.

15. The method of producing a semiconductor device according to claim 11, wherein the first gate line is formed so that the line width of the first gate line is smaller than the line width of the gate electrode and the line width of the second gate line.
